(19) United States
(12) Patent Application Publication
(10) Pub. No.: US 2025/0349956 A1
(43) Pub. Date: Nov. 13, 2025

(54) BATTERY MODULE

(71) Applicant: SK On Co., Ltd., Seoul (KR)

(72) Inventor: Jin Po PARK, Daejeon (KR)

(21) Appl. No.: 19/201,858

(22) Filed: May 7, 2025

(30) Foreign Application Priority Data
May 9, 2024 (KR) 10-2024-0061059

(51) Int. Cl. H01M 50/24; H01M 50/204; H01M 50/284

(52) U.S. Cl. CPC H01M 50/24; H01M 50/204; H01M 50/284

(57) ABSTRACT

The present disclosure relates to a battery module having significantly improved insulation properties. According to an aspect of the present disclosure, there is provided a battery module including: a cell stack including a plurality of battery cells; a flexible printed circuit board positioned on at least one surface of the cell stack; and a housing having an internal accommodation space in which the cell stack and the flexible printed circuit board are accommodated, wherein the flexible printed circuit board includes a base substrate, a metal layer positioned on the base substrate, and an insulating layer positioned on the metal layer, and the insulating layer includes a plurality of stacked polyimide layers, and a first adhesive layer positioned between the adjacent polyimide layers.

### CROSS-REFERENCE TO RELATED APPLICATIONS

This application claims priority under 35 U.S.C. § 119 to Korean Patent Application No. 10-2024-0061059, filed on May 9, 2024, in the Korean Intellectual Property Office, the disclosure of which is incorporated herein by reference in its entirety.

### TECHNICAL FIELD

The following disclosure relates to a battery module having significantly improved insulation properties.

### BACKGROUND

In recent years, a secondary battery, which may be charged and discharged, has been widely used as an energy source for a wireless mobile device, and has attracted attention as a power source for an electric vehicle (EV), a hybrid electric vehicle (HEV), and a plug-in hybrid electric vehicle (plug-in HEV), which have been developed to solve problems such as air pollution caused by existing gasoline and diesel vehicles using fossil fuels.

While small-sized mobile devices use one to three battery cells for each device, medium-sized and large-sized devices such as automobiles use a battery module or a battery pack obtained by electrically connecting a plurality of battery cells because high output and large capacity are necessary. Such a secondary battery may have a plurality of battery cells connected in series to provide the output and capacity required by a predetermined apparatus or device.

Meanwhile, although the lithium secondary battery has excellent electrical characteristics, the lithium secondary battery has low safety. For example, in the lithium secondary battery, in an abnormal operating state such as overcharging, overdischarging, exposure to high temperatures, or electrical short circuit, a decomposition reaction of battery components such as an active material and an electrolyte is caused, which results in generation of heat and gas, and the resulting high temperature and high pressure conditions further accelerate the decomposition reaction, ultimately resulting in ignition or explosion.

As a method of managing safety accidents, conventional medium-sized and large-sized battery modules or battery packs are equipped with a sensing device that may measure voltage and temperature of battery cells, and a battery management system (BMS) that controls the battery based on the measured values.

However, BMS is only a management system that detects risks and operates safety devices within the battery module or battery pack, and a fundamental solution to improve safety is still needed.

### SUMMARY

An embodiment of the present disclosure is directed to providing a flexible printed circuit board (FPCB) having excellent insulation properties used in a battery module and a battery module including the same.

Another embodiment of the present disclosure is directed to providing a battery module having improved safety.

Still another embodiment of the present disclosure is directed to providing a battery module with a significantly reduced defect rate in a manufacturing process.

The battery module of the present disclosure may be widely applied in green technology fields such as an electric vehicle, a battery charging station, and solar power generation and wind power generation using batteries. In addition, the battery module of the present disclosure may be used in an eco-friendly electric vehicle, a hybrid vehicle, and the like to prevent climate change by suppressing air pollution and greenhouse gas emissions.

In one general aspect, a battery module includes: a cell stack including a plurality of battery cells; a flexible printed circuit board positioned on at least one surface of the cell stack; and a housing having an internal accommodation space in which the cell stack and the flexible printed circuit board are accommodated, wherein the flexible printed circuit board includes a base substrate, a metal layer positioned on the base substrate, and an insulating layer positioned on the metal layer, and the insulating layer includes a plurality of stacked polyimide layers, and a first adhesive layer positioned between the adjacent polyimide layers.

In an exemplary embodiment, a sum of thicknesses of the plurality of polyimide layers may be from 5 μm to 50 μm.

In an exemplary embodiment, a thickness of the first adhesive layer may be from 1 μm to 50 μm.

In an exemplary embodiment, a thickness of the insulating layer may be from 15 μm to 100 μm.

In an exemplary embodiment, the flexible printed circuit board may have a heat deflection temperature of 200° C. or higher as measured according to ASTM D648, a breakdown voltage of 4,000 V to 6,000 V as measured according to ASTM D 3755, and a flame retardant rating of V−1 or higher as evaluated according to UL-94 VB flame retardancy standard.

In an exemplary embodiment, the insulating layer may have a structure in which two polyimide layers are stacked via the first adhesive layer.

In an exemplary embodiment, a thickness of each of the polyimide layers may be from 5 μm to 15 μm.

In an exemplary embodiment, the first adhesive layer may contain an adhesive and a flame retardant.

In an exemplary embodiment, the flame retardant may include at least one of an organic flame retardant, an inorganic flame retardant, or a combination thereof.

In an exemplary embodiment, the organic flame retardant may include one or more selected from the group consisting of a phosphorus-based flame retardant, a nitrogen-based flame retardant, a phosphorus-nitrogen-based flame retardant, and a halogen-based flame retardant.

In an exemplary embodiment, the inorganic flame retardant may include a metal oxide.

In an exemplary embodiment, the flexible printed circuit board may further include a second adhesive layer positioned between the base substrate and the metal layer.

In an exemplary embodiment, the flexible printed circuit board may further include a third adhesive layer positioned between the metal layer and the insulating layer.

In an exemplary embodiment, the base substrate may include an insulating material.

In an exemplary embodiment, the flexible printed circuit board may be disposed on the cell stack so that the insulating layer and the housing face each other.

Other features and aspects will be apparent from the following detailed description, the drawings, and the claims.

### BRIEF DESCRIPTION OF THE DRAWINGS

FIG. 1 is a cross-sectional view schematically illustrating a flexible printed circuit board included in a conventional battery module.

FIG. 2 is a cross-sectional view schematically illustrating a flexible printed circuit board according to an exemplary embodiment.

FIG. 3 is a view explaining the principle of improving insulation properties of a flexible printed circuit board according to an exemplary embodiment.

FIG. 4 is a perspective view schematically illustrating a battery module according to an exemplary embodiment.

### DETAILED DESCRIPTION OF EMBODIMENTS

Exemplary embodiments described in the present specification may be modified in various different forms, and the technology according to an exemplary embodiment is not limited to the exemplary embodiments described below. In addition, these exemplary embodiments are provided to more fully describe the present disclosure to those skilled in the art.

In addition, unless the context clearly indicates otherwise, singular forms used in the specification and the appended claims may be intended to include plural forms.

In addition, a numerical range used in the present specification includes upper and lower limits and all values within these limits, increments logically derived from a form and span of a defined range, all double limited values, and all possible combinations of the upper and lower limits in the numerical range defined in different forms. Unless otherwise specifically defined in the present specification, values out of the numerical range that may occur due to experimental errors or rounded values also fall within the defined numerical range.

Furthermore, throughout the specification, unless explicitly described to the contrary, “including” a certain component will be understood to imply further inclusion of other components rather than the exclusion of any other components.

In the present specification, when a part such as a layer, a film, a region, or a plate is referred to as being “on” or “above”, it may be “directly on” another part or an intervening part may also be present therebetween.

The terms “first”, “second”, and the like as used in the present specification may be used to describe various components, but the components should not be limited by the terms. The terms are only used to distinguish one component from another component.

According to a first aspect of the present disclosure, there is provided a battery module including: a cell stack including a plurality of battery cells; a flexible printed circuit board positioned on at least one surface of the cell stack; and a housing having an internal accommodation space in which the cell stack and the flexible printed circuit board are accommodated, wherein the flexible printed circuit board includes a base substrate, a metal layer positioned on the base substrate, and an insulating layer positioned on the metal layer, and the insulating layer includes a plurality of stacked polyimide layers, and a first adhesive layer positioned between the adjacent polyimide layers.

The battery module according to an exemplary embodiment of the present disclosure may secure excellent insulation properties by the other polyimide layers even when a defect occurs in one of the plurality of polyimide layers. In addition, since the insulation properties are maintained even when a defect occurs in all of the plurality of polyimide layers, unless the defect occurs in the same location in each layer, the possibility of securing excellent insulation properties may be significantly increased. Accordingly, the problem of safety degradation due to short-circuit occurrence and the problem of increased defect rate in the manufacturing process may be solved.

In an exemplary embodiment, a flexible printed circuit board is disposed on a cell stack so that an insulating layer having a structure in which a plurality of polyimide layers are stacked via a first adhesive layer faces a conductive component such as a housing, such that the insulation properties may be significantly improved without providing an additional insulating unit, thereby increasing an energy density per volume of the battery module.

In an exemplary embodiment, the insulating layer may include a plurality of polyimide layers and a first adhesive layer that bonds each polyimide layer and a polyimide layer adjacent thereto. That is, the insulating layer may include n polyimide layers and (n−1) first adhesive layers that bond each polyimide layer and a polyimide layer adjacent thereto. For example, in a case where the insulating layer includes two polyimide layers, the insulating layer may have a structure in which a polyimide layer, a first adhesive layer, and a polyimide layer are sequentially stacked, and in a case where the insulating layer has three polyimide layers, the insulating layer may have a structure in which a polyimide layer, a first adhesive layer, a polyimide layer, a first adhesive layer, and a polyimide layer are sequentially stacked.

In an exemplary embodiment, a sum of thicknesses of the two or more polyimide layers may be 5 μm or more, 10 μm or more, 15 μm or more, 20 μm or more, 60 μm or less, 50 μm or less, or a value between the above values. For example, the sum of the thicknesses of the two or more polyimide layers may be from 5 μm to 60 μm, 10 μm to 60 μm, 15 μm to 55 μm, or 20 μm to 50 μm. When the thickness range described above is satisfied, the battery module may have improved mechanical properties and may thus have improved insulation properties. Specifically, the battery module according to an exemplary embodiment has the thickness range described above and includes the insulating layer including a plurality of polyimide layers, such that a phenomenon of crack formation on the polyimide layer due to folding may be effectively suppressed, and as a result, significantly improved mechanical properties and insulation properties may be obtained.

In an exemplary embodiment, a thickness of the first adhesive layer may be 1 μm or more, 5 μm or more, 50 μm or less, 30 μm or less, 20 μm or less, or a value between the above values. For example, the thickness of the first adhesive layer may be from 1 μm to 50 μm, 1 μm to 30 μm, or 5 μm to 20 μm. In this case, the thickness of the first adhesive layer may refer to a total thickness of the first adhesive layer included in the insulating layer. When the thickness range described above is satisfied, the battery module may have improved mechanical properties and may thus have improved insulation properties.

In an exemplary embodiment, a total thickness of the insulating layer may be 15 μm or more, 20 μm or more, 25 μm or more, 100 μm or less, 75 μm or less, 50 μm or less, or a value between the above values. For example, the total thickness of the insulating layer may be from 15 μm to 100 μm, 20 μm to 75 μm, 15 μm to 50 μm, or 25 μm to 50 μm. When the insulating layer satisfies the thickness range described above, the battery module may have improved mechanical properties and may thus have improved insulation properties.

In an exemplary embodiment, the flexible printed circuit board may have a heat deflection temperature of 200° C. or higher as measured according to ASTM D648, a breakdown voltage (BDA) of 4,000 V to 6,000 V as measured according to ASTM D149, and a flame retardant rating of V−1 or higher as evaluated according to UL-94 VB flame retardancy standard. When the flexible printed circuit board satisfies the heat deflection temperature, the breakdown voltage, and the flame retardant rating as described above, the battery module may have more significantly improved insulation properties, thereby effectively reducing a manufacturing defect rate of the battery module. Specifically, as the flexible printed circuit board satisfies all of the properties described above, the phenomenon of crack formation on the polyimide layer due to folding may be effectively suppressed, and as a result, significantly improved mechanical properties and insulation properties may be obtained.

Specifically, the heat deflection temperature (HDT) of the flexible printed circuit board may be 150° C. or higher, 180° C. or higher, or 200° C. or higher, and may be, but is not limited to, 800° C. or lower, 700° C. or lower, 600° C. or lower, or a value between the above values. As the flexible printed circuit board has excellent heat resistance characteristics at the heat deflection temperature in the above range, even when a high temperature environment is created when the battery module is operated, the safety of the flexible printed circuit board may be improved with excellent heat resistance. In addition, the possibility of damage to the flexible printed circuit board during manufacturing and use may be significantly reduced.

For example, the heat deflection temperature (HDT) may be measured according to ASTM D648, and specifically, the heat deflection temperature (HDT) may be a temperature at which the flexible printed circuit board is deformed by 0.25 mm when the flexible printed circuit board is placed on a support of a heat deformation tester (INSTRON CEAST, HV3S) and heated at a heating rate of 2±0.2° C./min while applying a bending stress of 264 psi to the center.

Specifically, the breakdown voltage (BDV) of the flexible printed circuit board may be from 4 kV to 6 kV, 4.2 kV to 5.8 kV, or 4.5 kV to 5.5 kV. The breakdown voltage (BDV) may be measured according to ASTM D149, and specifically, the breakdown voltage (BDV) may be a voltage (kV) when a leakage current value is 5 mA, the leakage current value being measured under a condition where the flexible printed circuit board is disposed between electrodes of a withstand voltage tester (19052 model, Chroma ATE Inc.) at room temperature (25° C.) and then the applied voltage is increased to 5 kV/10 sec.

Specifically, the flame retardant rating of the flexible printed circuit board is evaluated according to the UL-94 VB flame retardancy standard, may be V−1 or higher or V−0 or higher, and advantageously may be 5 VB.

In an exemplary embodiment, the insulating layer may have a structure in which two polyimide layers are stacked via a first adhesive layer, and in this case, a thickness of each polyimide layer may be 2.5 μm or more, 5 μm or more, 25 μm or less, 20 μm or less, 15 μm or less, or a value between the above values. For example, the thickness of each polyimide layer may be from 2.5 μm to 25 μm or 2.5 μm to 20 μm, and may be 5 μm to 15 μm from the viewpoint of improving the mechanical properties and insulation properties of the battery module.

In an exemplary embodiment, the plurality of polyimide layers included in the insulating layer may have the same or different properties, and it is preferable that the plurality of polyimide layers have the same properties from the viewpoint of improving the mechanical properties and insulation properties of the battery module.

In an exemplary embodiment, the first adhesive layer may contain an adhesive, and the adhesive may have adhesive properties imparted by heat compression. Any adhesive may be selected and used without limitation as long as it is an adhesive material used in the art. Examples of the adhesive material include one or a combination of two or more selected from the group consisting of an ethylene vinyl acetate (EVA)-based polymer, an acrylic-based polymer, an epoxy-based polymer, an olefin-based polymer, a rubber-based polymer, an amide-based polymer, and a urethane-based polymer, but the adhesive material may be substituted with other components without departing from the scope of the present disclosure.

In an exemplary embodiment, the first adhesive layer may further contain a flame retardant, and may thus contain an adhesive and a flame retardant. As the first adhesive layer further contains a flame retardant, a battery module having significantly improved thermal stability as well as insulation properties may be provided.

In an exemplary embodiment, the flame retardant may include an organic flame retardant, an inorganic flame retardant, or a combination thereof. The organic flame retardant may include one or more selected from the group consisting of a phosphorus-based flame retardant, a nitrogen-based flame retardant, a phosphorus-nitrogen-based flame retardant, and a halogen-based flame retardant, and the inorganic flame retardant may include a metal oxide.

For example, as the phosphorus-based flame retardant, a phosphate compound, a phosphonate compound, a phosphinate compound, a phosphineoxide compound, a phosphazene compound, or a metal salt thereof may be used. As the nitrogen-based flame retardant, piperazine pyrophosphate, melamine polyphosphate, ammonium polyphosphate (APP), melamine cyanurate, or a combination thereof may be used. As the halogen-based flame retardant, decabromodiphenyl oxide, decabromodiphenyl ethane, decabromodiphenyl ether, tetrabromobisphenol A, a tetrabromobisphenol A-epoxy oligomer, a brominated epoxy oligomer, octabromotrimethylphenylindane, ethylenebistetrabromophthalimide, 2,4,6-tris(2,4,6-tribromophenoxy)-1,3,5-triazine, or a combination thereof may be used. The inorganic flame retardant may include a metal oxide such as magnesium hydroxide, aluminum hydroxide, antimony trioxide, antimony tetroxide, antimony pentoxide, sodium antimony carbonate, metallic antimony, antimony trichloride, antimony pentachloride, barium metaborate, zirconium oxide, zinc borate, zinc stannate, or a combination thereof. As an example, the flame retardant may include a phosphorus-nitrogen-based flame retardant containing ammonium polyphosphate (APP) and an inorganic flame retardant containing aluminum hydroxide.

In an exemplary embodiment, the flexible printed circuit board may further include a second adhesive layer positioned between the base substrate and the metal layer to bond the base substrate and the metal layer. A thickness of the second adhesive layer may be from 1 μm to 50 μm, 10 μm to 50 μm, or 20 μm to 40 μm, but is not limited thereto. An adhesive used in the second adhesive layer may be the same as the adhesive that may be used in the first adhesive layer described above, and a detailed description thereof is omitted.

In an exemplary embodiment, the flexible printed circuit board may further include a third adhesive layer positioned between the metal layer and the insulating layer to bond the metal layer and the insulating layer. A thickness of the third adhesive layer may be from 1 μm to 50 μm, 1 μm to 30 μm, or 5 μm to 20 μm, but is not limited thereto. An adhesive used in the third adhesive layer may be the same as the adhesive that may be used in the first adhesive layer described above, and a detailed description thereof is omitted.

In an exemplary embodiment, the base substrate may include an insulating material. The insulating material may be one or more selected from the group consisting of polyimide, polyamideimide, polyester, polyphenylene sulfide, polyether sulfone, polyether ether ketone, aramid, polycarbonate, and polyarylate, and specifically, may be polyimide. A thickness of the base substrate may be 1 from μm to 50 μm, 10 μm to 50 μm, or 20 μm to 40 μm, but is not limited thereto.

In an exemplary embodiment, the metal layer may include a conductor of copper, silver, gold, or nickel, and specifically, may include copper in terms of electrical conductivity. The metal layer may be manufactured according to a method known in the art, and for example, may be manufactured by forming a thin metal film on the base substrate (or the second adhesive layer) by a method such as deposition or plating, and forming a pattern through photolithography. A thickness of the metal layer may be from 1 μm to 50 μm, 10 μm to 50 μm, or 20 μm to 50 μm, but is not limited thereto.

In an exemplary embodiment, a total thickness of the flexible printed circuit board is not limited as long as it satisfies the thickness of each layer described above, and may be, for example, from 20 μm to 500 μm, 50 μm to 250 μm, or 50 μm to 200 μm.

In an exemplary embodiment, the flexible printed circuit board may be electrically connected to some or all of a plurality of battery cells and may serve to transmit information of the battery cells to a battery management system (BMS). Specifically, the battery module may further include a sensor provided on the battery cell for measuring a voltage and/or temperature of the battery cell and a battery management system. The flexible printed circuit board may be electrically connected to the sensor and the battery management system, respectively, and may transmit information (voltage and/or temperature) collected from the sensor to the battery management system.

In an exemplary embodiment, the housing included in the battery module may be provided in a form that surrounds the entire cell stack. A material of the housing is not particularly limited as long as it is a material having excellent thermal conductivity, and may be, for example, an aluminum-based alloy. Examples of the aluminum-based alloy include an Al—Mg-based aluminum alloy, an Al—Mg—Si-based aluminum alloy, an Al—Si-based aluminum alloy, and an Al—Si—Cu-based aluminum alloy. A thickness of the housing may be on the order of 10⁰ mm to 10¹ mm, and, as a practical example, may be on the order of 1 mm to 30 mm, but is not limited thereto.

In an exemplary embodiment, a battery pack may be formed by accommodating a battery cell stack and a flexible printed circuit board positioned on at least one surface of the battery cell stack inside a pack case.

As described above, in the battery pack including the flexible printed circuit board according to an exemplary embodiment of the present disclosure, an insulating layer having a structure in which a plurality of polyimide layers are stacked via a first adhesive layer is disposed on at least one surface of the battery cell stack, such that significantly improved insulation properties may be obtained. Specifically, the secondary battery pack may secure excellent insulation properties by the other polyimide layers even when a defect occurs in one of the plurality of polyimide layers. In addition, since the insulation properties are maintained even when a defect occurs in all of the plurality of polyimide layers, unless the defect occurs in the same location in each layer, the possibility of securing excellent insulation properties may be significantly increased. Accordingly, the problem of safety degradation due to short-circuit occurrence and the problem of increased defect rate in the manufacturing process may be solved. In addition, since two or more polyimide layers are arranged on a side of a conductive component such as a pack case in the secondary battery pack, there is no need for an additional insulating unit, and thus, the battery pack may have a high energy density while significantly improving the insulation properties.

Each component included in the secondary battery pack according to a second aspect may be applied in the same manner as each component included in the battery module according to the first aspect described above, and a detailed description thereof is omitted.

In an exemplary embodiment, the battery pack is not limited to a structure and may have various shapes. For example, the battery pack may have a structure such as a cell to pack in which the battery cell stack and the flexible printed circuit board are directly accommodated in the pack housing, a cell to body, or the like. In this case, the flexible printed circuit board may be disposed to face the pack case to improve insulation performance. Alternatively, a battery module in which a battery cell stack and a flexible printed circuit board are accommodated in a housing may be accommodated inside a pack case to form a battery pack.

In an exemplary embodiment, the pack case may be provided to surround all of a plurality of battery cell stacks. The pack case may be formed of a metal material to ensure rigidity, but is not limited thereto. For example, at least a part of the pack case may be formed of aluminum to enhance the heat dissipation effect.

Hereinafter, the present disclosure will be described in detail with reference to the accompanying drawings. However, the description is merely exemplary and the present disclosure is not limited to specific exemplary embodiments described by way of example.

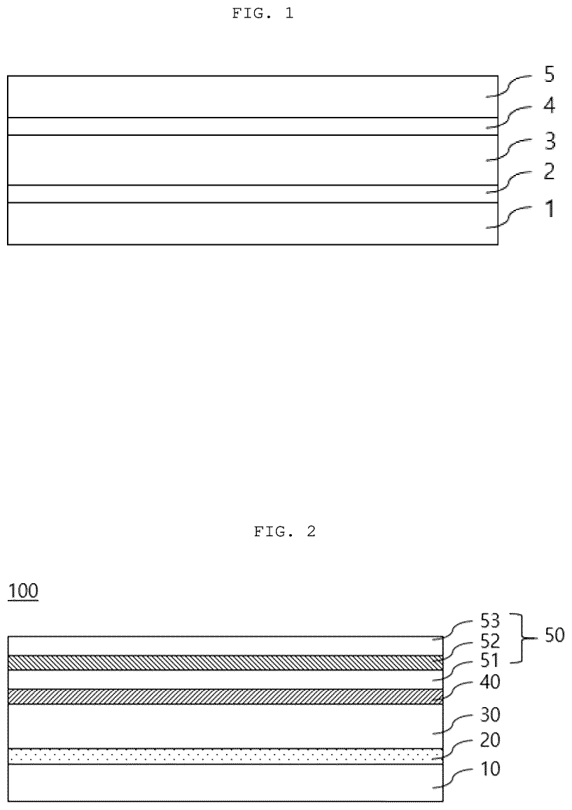

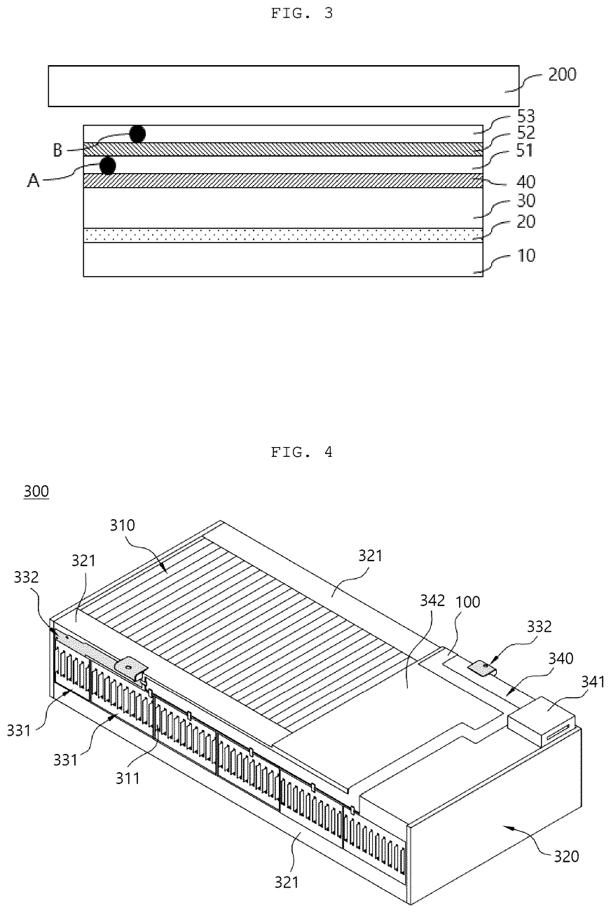

FIG. 1 is a view illustrating a cross-sectional structure of a flexible printed circuit board included in a conventional battery module, and FIG. 2 is a view illustrating a cross-sectional structure of a flexible printed circuit board included in a battery module or a battery pack. FIG. 3 is a view explaining the principle of improving insulation properties of a flexible printed circuit board according to an exemplary embodiment, and FIG. 4 is a view illustrating a structure of a battery module according to an exemplary embodiment.

Referring to FIG. 1, the flexible printed circuit board included in the conventional battery module or pack includes: a base substrate 1; a metal layer 3 positioned on the base substrate 1; an insulating layer 5 formed of a single polyimide layer positioned on the metal layer 3; an adhesive layer 2 for bonding the base substrate 1 and the metal layer 3; and an adhesive layer 4 for bonding the metal layer 3 and the insulating layer 5. When the insulating layer 5 is damaged due to the occurrence of pin holes or dents in the single polyimide layer, there is a significantly high possibility that a short circuit will occur between the metal layer 3 and a conductive component 200 such as a housing of the battery module or a case of the secondary battery pack.

Referring to FIG. 2, a flexible printed circuit board 100 included in the battery module or pack according to an exemplary embodiment includes: a base substrate 10; a metal layer 30 positioned on the base substrate 10; an insulating layer 50 having a structure in which two polyimide layers 51 and 53 positioned on the metal layer 30 are stacked via a first adhesive layer 52; a second adhesive layer 20 for bonding the base substrate 10 and the metal layer 30; and a third adhesive layer 40 for bonding the metal layer 30 and the insulating layer 50. FIG. 2 illustrates the flexible printed circuit board 100 including the insulating layer 50 in which the two polyimide layers 51 and 53 are stacked, but this is only an example and the present disclosure is not limited thereto. In addition, FIG. 2 illustrates the flexible printed circuit board 100 including the second adhesive layer 20 and the third adhesive layer 40, but the present disclosure is not limited thereto and does not exclude other exemplary embodiments that do not include the second adhesive layer 20 and the third adhesive layer 40.

The battery module and the battery pack according to an exemplary embodiment include the flexible printed circuit board in which an insulating layer having a structure in which two or more polyimide layers are stacked is disposed to face a conductive component such as a housing of the battery module or a case of the secondary battery pack, such that the possibility of a short circuit occurring between the conductive component and the metal layer may be significantly reduced. Accordingly, the present disclosure may provide a battery module and a battery pack having significantly improved insulation properties. Specifically, referring to FIG. 3, even when a defect occurs at a point A of the polyimide layer 51, excellent insulation properties may be maintained by the other polyimide layer 53. Even when a defect occurs at a point B of the polyimide layer 53, excellent insulation properties may be maintained by the other polyimide layer 51. In addition, even when a defect occurs simultaneously at the point A of the polyimide layer 51 and the point B of the polyimide layer 53, excellent insulation properties may be maintained unless the defect occurs at the same location in each layer and the point A and the point B are connected. That is, the battery module and the battery pack according to an exemplary embodiment may have significantly improved insulation properties by significantly reducing the possibility of a short circuit occurring between the conductive component 200 and the metal layer 30.

Referring to FIG. 4, the battery module according to an exemplary embodiment of the present disclosure includes: a battery cell stack 310 in which a plurality of battery cells are stacked; a housing 320 that accommodates the battery cell stack 310; a bus bar assembly that is arranged on a side of the housing 320 and electrically connected to the battery cells of the battery cell stack 310; and a sensing module 340 that interconnects the bus bar assembly and a flexible printed circuit board 100.

The battery cells of the battery cell stack 310 are stacked and arranged in one direction within the housing 320 and are electrically connected to adjacent battery cells, and each battery cell may output or store electrical energy.

The plurality of battery cells included in the battery cell stack 310 may be electrically connected to each other through the bus bar assembly. The bus bar assembly may be disposed so that at least a part of the bus bar assembly faces the battery cell stack 310 in a direction perpendicular to a cell stacking direction.

The bus bar assembly may include a bus bar 332 electrically connecting one battery cell to another battery cell and a bus bar plate 331 supporting the bus bar 332. The bus bar plate 331 may be joined to a side plate 321 as a conductive member that electrically connects one or more electrode tabs 311 exposed to the outside through outlet holes of the side plate 321. As is known to those skilled in the art, the bus bar plate 331 may be embedded in and joined to the side plate 321 with one side exposed to the outside. In addition, the bus bar plate 331 arranged on the side plate 321 may be arranged to be mutually insulated from the bus bar plate arranged adjacently on the same side plate.

The bus bar 332 may include a conductive material to be electrically connected to the electrode tabs 311 of the battery cells to electrically connect the plurality of battery cells to each other. Various welding methods, including laser welding, may be applied to the connection between the bus bar 332 and the lead tabs. However, the connection method is not limited to welding, and any connection method capable of electrically conducting the two metallic materials may be used.

A battery module 300 may further include a sensing module 340 connected to the bus bar assembly. The sensing module 340 may include a temperature sensor, a voltage sensor, or the like. The sensing module 340 may sense a status of the battery cells and output the sensed information to the outside of the battery module 300.

The sensing module 340 may include a flexible printed circuit board 100 that interconnects a pair of bus bars 332 positioned on both sides in a direction in which the electrode tabs 311 extend, a connector 341 that transmits information such as sensed voltage and temperature to the outside, and a support portion 342 that supports the flexible printed circuit board 100 and the connector 341.

The flexible printed circuit board 100 may transmit and receive electric signals for sensed information by being in contact with each bus bar plate 331 arranged along an outer surface of the side plate 321. In addition, the flexible printed circuit board 100 is fixed to the side plate 321 and the support portion 342, such that a stress applied to the flexible printed circuit board 100 may be dispersed, and a lifting phenomenon may be prevented, thereby minimizing damage to the flexible printed circuit board 100.

As described above, the flexible printed circuit board 100 according to an exemplary embodiment of the present disclosure not only significantly reduces the possibility of a defect occurring due to deformation such as folding, but also maintains excellent insulation properties even when a defect occurs in the polyimide layer included in the flexible printed circuit board 100. Accordingly, the defect rate of the battery module 300 due to a defect in the flexible printed circuit board 100 may be significantly reduced, and the safety of the battery module 300 may be improved with excellent durability even under high temperature and high pressure conditions.

In addition, the flexible printed circuit board 100 is disposed on the battery cell stack 310 so that the insulating layer of the flexible printed circuit board 100 faces the conductive component such as a housing (not shown), such that the battery module 300 may have excellent insulation properties without providing an additional insulating unit, thereby significantly improving the energy density per volume of the battery module.

Hereinafter, examples of the present disclosure will be further described with reference to specific experimental examples. The examples and comparative examples included in the experimental examples are merely illustrative of the present disclosure and do not limit the scope of the accompanying claims, it is obvious to those skilled in the art that various modifications and alterations may be made without departing from the spirit and scope of the present disclosure, and it is obvious that these modifications and alterations are within the accompanying claims.

### Example 1

A flexible printed circuit board as illustrated in FIG. 2 was prepared. Specifically, a flexible copper foil laminate (Hanwha e-ssential Corporation, HGLS-S211EM), in which a base substrate 10 including a polyimide film having a thickness of 25 μm, a second adhesive layer 20 having a thickness of 30 μm, and a metal layer 30 including a copper thin film having a thickness of 35 μm with a pattern formed were sequentially stacked, was used. As for polyimide layers 51 and 53, a first adhesive layer 52, and a third adhesive layer 40, two sheets of polyimide film (PI Advanced Materials Co. Ltd., GF100), each including an adhesive layer containing an epoxy-based polymer having a thickness of 10 μm positioned on one surface of a polyimide layer having a thickness of 12.5 μm, were stacked on the metal layer 30 and used.

### Example 2

A flexible printed circuit board was prepared in the same manner as in Example 1, except that a polyimide film in which a thickness of each of the two polyimide layers 51 and 53 was 30 μm was used.

### Example 3

A flexible printed circuit board was prepared in the same manner as in Example 1, except that a flame retardant containing ammonium polyphosphate (APP) and aluminum hydroxide (Al(OH)₃) was further contained in the first adhesive layer 52.

### Example 4

A flexible printed circuit board was prepared in the same manner as in Example 1, except that a polyimide layer having a thickness of 12.5 μm and an adhesive layer having a thickness of 10 μm were stacked in three layers to form an insulating layer.

### Comparative Example 1

A flexible printed circuit board as illustrated in FIG. 1 was prepared. Specifically, a flexible copper foil laminate (Hanwha e-ssential Corporation, HGLS-S211EM), in which a base substrate 1 including a polyimide film having a thickness of 25 μm, a second adhesive layer 2 having a thickness of 30 μm, and a metal layer 30 including a copper thin film having a thickness of 35 μm with a pattern formed were sequentially stacked, was used, and as for an adhesive layer 4 and an insulating layer 5, a polyimide film (PI Advanced Materials Co. Ltd., GF100), in which an adhesive layer 4 having a thickness of 10 μm was positioned on one surface of a polyimide insulating layer 5 having a thickness of 25 μm, was used.

### Evaluation Examples

The heat resistance of the flexible printed circuit board was evaluated by measuring a heat deflection temperature (HDT) according to ASTM D648. Specifically, the heat deflection temperature (HDT) was evaluated for the heat resistance by placing the flexible printed circuit board manufactured in each of the examples or comparative examples on a support of a heat deformation tester (INSTRON CEAST, HV3S) and measuring a temperature when the flexible printed circuit board was deformed by 0.25 mm at the time of heating the flexible printed circuit board at a heating rate of 2±0.2° C./min while applying a bending stress of 264 psi to the center.

A breakdown voltage of the flexible printed circuit board was measured according to ASTM D 3755. Specifically, the breakdown voltage (BDV) was measured under a condition in which the flexible printed circuit board manufactured in each of the examples or comparative examples was disposed between electrodes of a withstand voltage tester (19052 model, Chroma ATE Inc.) at room temperature (25° C.) and the applied voltage was increased to 5 kV/10 sec, and a voltage (kV) at which a leakage current value was 5 mA was used.

A flame retardant rating of the flexible printed circuit board was evaluated according to UL-94 VB flame retardancy standard.

A bending test was performed to evaluate the mechanical properties of the flexible printed circuit board. Specifically, when a process of folding the flexible printed circuit board manufactured in each of the examples or comparative examples in half, applying a load of 5 kg to the folded flexible printed circuit board, and unfolding a folded portion again was set as one cycle, and the process was repeated, the number of times when the measured leakage current began to exceed 10 mA after applying a DC voltage of 1,000 kV was confirmed. At this time, the leakage current was measured using a leakage current tester (HIOKI, ST5540).

The evaluation results are shown in Table 1.

TABLE 1

| | Example | Example | Example | Example | Example | Comparative |
|---|---|---|---|---|---|---|
| | 1 | 2 | 3 | 4 | 5 | Example 1 |
| Number of | 2 | 2 | 2 | 3 | 2 | 1 |
| polyimide layers | | | | | | |
| included in | | | | | | |
| insulating layer | | | | | | |
| Thickness of | 12.5 | 30 | 12.5 | 12.5 | 7.5 | 25 |
| polyimide layer | | | | | | |
| (μm) | | | | | | |
| Heat deflection | 270 | 270 | 270 | 270 | 270 | 270 |
| temperature (° C.) | | | | | | |
| Breakdown voltage | 2.5 | 6 | 2.5 | 3.7 | 1.5 | 0.5 |
| (kV) | | | | | | |
| Flame retardant | V-O | V-O | 5 VB | V-0 | V-0 | V-O |
| rating | | | | | | |
| Bending test | 64 times | 32 times | 64 times | 76 times | 92 times | 64 times |
| result | | | | | | |

As shown in Table 1, it was found that the flexible printed circuit boards of Examples 1 to 4 had excellent breakdown voltage characteristics, and even when the bending stress was repeatedly applied 40 times or more, a leakage current of 10 mA or less was exhibited, which showed that the flexible printed circuit boards of Examples 1 to 4 had excellent insulation properties. Specifically, in the case of Examples 1 and 3, the heat deflection temperature was measured to be 270° C. and the breakdown voltage was measured to be 2.5 kV, when the bending stress was repeatedly applied 64 times, the leakage current of the flexible printed circuit board exceeded 10 mA, and therefore, it was found that the flexible printed circuit board maintains excellent insulation properties even when deformed.

In particular, the flexible printed circuit board of Example 3, in which a flame retardant was additionally contained in the first insulating layer, exhibited flame retardant characteristics with a flame retardant rating of 5 VB, which was higher than the flame retardant rating (V−0) of the flexible printed circuit board of Example 1.

In addition, in the case of the flexible printed circuit board of Example 5 in which a thickness of the polyimide layer was 7.5 μm, the bending test result was increased to 92 times compared to Example 1, and thus, the mechanical properties were improved, but the breakdown voltage was reduced to 1.5 kV because the thickness of the polyimide layer was thinner than that of Example 1.

In the case of the flexible printed circuit board of Example 4 in which the number of polyimide layers included in the insulating layer increased to three, as the number of stacked polyimide layers increased and the total thickness of the insulating layer increased, the breakdown voltage increased to 6 kV compared to Example 1, but the mechanical properties were deteriorated as the thickness of the polyimide layer increased because the bending test result was decreased to 32 times.

In the case of the flexible printed circuit board manufactured by the method of Example 2, since the thickness of the polyimide layer was thicker than that of the flexible printed circuit board of Example 1, the total thickness of the insulating layer increased to 60 μm, and thus, the breakdown voltage increased to 6 kV, but, when the bending stress was repeatedly applied 32 times, due to crack formation according to the increased thickness, the leakage current of the flexible printed circuit board increased rapidly, resulting in somewhat lower durability than that of Example 1.

On the other hand, in Comparative Example 1 in which one layer of polyimide film was included in the flexible printed circuit board, a significantly lower breakdown voltage (0.5 kV) was shown compared to Example 1, even though the thickness of the polyimide layer was 25 μm. Defects such as pinholes, dents, and scratches that occur in a single layer of polyimide film were exposed on the surface of the flexible printed circuit board, resulting in a significant decrease in the insulation properties. Therefore, it was found that, when the flexible printed circuit board of Comparative Example 1 is applied to a battery module or a secondary battery pack, there is a significantly high risk of a problem in which a short circuit occurs between the conductive component facing the insulating layer and the metal layer, resulting in a loss of insulating performance.

Accordingly, in the flexible printed circuit board included in the battery module according to the present disclosure, an insulating layer was formed by stacking two or more layers of polyimide films on a metal layer, such that the flexible printed circuit board had excellent insulation performance without providing an additional insulating unit. Even when a defect occurred in the polyimide layer, the insulation performance was maintained by the other polyimide layers, such that the insulation performance was improved and the defect rate of the manufactured battery module was reduced. In particular, since a flexible printed circuit board having excellent insulation properties is manufactured even when polyimide is stacked in two layers, the thickness of the flexible printed circuit board may be minimized, such that the capacity per unit volume of the battery module including the same may be improved.

As set forth above, the battery module of the present disclosure includes the flexible printed circuit board having excellent insulation properties, such that the battery module may have significantly improved insulation properties.

Further, the battery module of the present disclosure may have significantly improved safety and significantly lower manufacturing process defect rate.

The above description is merely an example of applying the principles of the present disclosure, and other configurations may be further included without departing from the scope of the present disclosure.

[Detailed Description of Main Elements]

| | |
|---|---|
| 1, 10: Base substrate | 2, 4: Adhesive layer |
| 3, 30: Metal layer | 5, 50: Insulating layer |
| 20: Second adhesive layer | 40: Third adhesive layer |
| 51, 53: Polyimide layer | 52: First adhesive layer |
| 100: Flexible printed circuit board | 200: Conductive |
| | component |
| A, B: Defect | 300: Battery module |
| 310: Battery cell stack | 311: Electrode tab |
| 320: Housing | 321: Side plate |
| 331: Bus bar plate | 332: Bus bar |
| 340: Sensing module | 341: Connector |
| 342: Support portion | |

What is claimed is:

1. A battery module comprising:
a cell stack including a plurality of battery cells;
a flexible printed circuit board positioned on at least one surface of the cell stack; and
a housing having an internal accommodation space in which the cell stack and the flexible printed circuit board are accommodated,
wherein the flexible printed circuit board includes a base substrate, a metal layer positioned on the base substrate, and an insulating layer positioned on the metal layer, and
the insulating layer includes a plurality of stacked polyimide layers, and a first adhesive layer positioned between the adjacent polyimide layers.

2. The battery module of claim 1, wherein a sum of thicknesses of the plurality of polyimide layers is from 5 μm to 50 μm.

3. The battery module of claim 1, wherein a thickness of the first adhesive layer is from 1 μm to 50 μm.

4. The battery module of claim 1, wherein a thickness of the insulating layer is from 15 μm to 100 μm.

5. The battery module of claim 1, wherein the flexible printed circuit board has a heat deflection temperature of 200° C. or higher as measured according to ASTM D648, a breakdown voltage of 4,000 V to 6,000 V as measured according to ASTM D 3755, and a flame retardant rating of V−1 or higher as evaluated according to UL-94 VB flame retardancy standard.

6. The battery module of claim 1, wherein the insulating layer has a structure in which two polyimide layers are stacked via the first adhesive layer.

7. The battery module of claim 6, wherein a thickness of each of the polyimide layers is from 5 μm to 15 μm.

8. The battery module of claim 1, wherein the first adhesive layer contains an adhesive and a flame retardant.

9. The battery module of claim 8, wherein the flame retardant includes at least one of an organic flame retardant, an inorganic flame retardant, or a combination thereof.

10. The battery module of claim 9, wherein the organic flame retardant includes one or more selected from the group consisting of a phosphorus-based flame retardant, a nitrogen-based flame retardant, a phosphorus-nitrogen-based flame retardant, and a halogen-based flame retardant.

11. The battery module of claim 9, wherein the inorganic flame retardant includes a metal oxide.

12. The battery module of claim 1, wherein the flexible printed circuit board further includes a second adhesive layer positioned between the base substrate and the metal layer.

13. The battery module of claim 1, wherein the flexible printed circuit board further includes a third adhesive layer positioned between the metal layer and the insulating layer.

14. The battery module of claim 1, wherein the base substrate includes an insulating material.

15. The battery module of claim 1, wherein the flexible printed circuit board is disposed on the cell stack so that the insulating layer and the housing face each other.
